(19) United States
(12) Patent Application Publication
(10) Pub. No.: US 2011/0286193 A1
(43) Pub. Date: Nov. 24, 2011

(54) ASSEMBLY OF AT LEAST TWO ELECTRIC BOARDS

(75) Inventors: Marc DUARTE, VILLEMOMBLE (FR); Benjamin THIERRY, PALIS (FR); Benjamin TOUZET, NEUILLY-SUR-SEINE (FR)

(73) Assignee: VALEO VISION, Bobigny Cedex (FR)

(21) Appl. No.: 13/112,049

(22) Filed: May 20, 2011

(30) Foreign Application Priority Data
May 21, 2010 (FR) 1053992

(51) Int. Cl. H05K 1/14

(52) U.S. Cl. 361/803

(57) ABSTRACT

An assembly of at least two electric boards, and in particular two printed circuit boards, the two boards being welded to one another, wherein at least one of the two boards comprises at least one orifice which shows a trace of the welding.

### CROSS-REFERENCE TO RELATED APPLICATIONS

This application claims priority to French Application No. 1053992 filed May 21, 2010, which application is incorporated herein by reference and made a part hereof.

### BACKGROUND OF THE INVENTION

1. Field of the Invention

The invention relates in particular to an assembly of at least two electric boards, and in particular, to two printed circuit boards, which assembly is used in particular in a motor vehicle.

2. Description of the Related Art

U.S. Pat. No. 6,919,529 describes a method for providing an electrical connection between a flexible printed circuit board and an electrical component. This method uses a laser for the welding. This method has the disadvantage that it does not make it possible to check easily the quality of the electrical connection.

What is needed, therefore, is a system and method for improving assembly of circuit boards.

### SUMMARY OF THE INVENTION

The object of the invention is in particular to propose a method for improved electrical connection.

The subject of the invention is thus an assembly of at least two electric boards, and in particular two printed circuit boards, the two boards being welded to one another, wherein at least one of the two boards comprises at least one orifice which shows a trace of the welding.

By means of the invention, because of the presence of an orifice which shows a trace of the welding, it is possible to carry out easily a check on the quality of the welding, for example by using a standard automatic means for optical inspection.

The orifice which shows the trace of the welding can for example be substantially circular, or have any other appropriate form.

The orifice can have a closed periphery, and be spaced from the edge of the corresponding board, or, as a variant, this orifice can be open on this edge, and form a slot for example.

The invention also makes it possible to obtain an assembly at a reduced cost, since, if so wished, it does not need any additional parts for the connection.

In addition, the invention permits good repeatability of the operations, and guarantees satisfactory mechanical strength of the assembly.

According to the present invention, “welding” means in particular an operation for assembly of two elements by means of addition of metal which is fused by heat. “Welding” also means brazing.

According to one embodiment of the invention, at least one of the boards is a flexible printed circuit board.

As a variant, at least one of the boards is a rigid printed circuit board.

If required, the two boards are rigid printed circuit boards, or, as a variant, the two boards are flexible printed circuit boards.

The welding trace can correspond to a deposit of welding material, for example tin. This welding trace can for example have the form of a meniscus.

According to one embodiment of the invention, the deposit of welding material extends through the orifice in the board.

Preferably, each board comprises at least one conductive track, and the deposit of welding material joins the conductive track of one of the boards to the conductive track of the other board.

If applicable, at least one of the boards comprises a plurality of orifices, each showing a welding trace.

Preferably, at least one of the boards, which for example is rigid, comprises at least one pin, and for example a plurality of pins, which is/are designed to be engaged in the orifice in the other board, and the deposit of welding material is for example in contact with this pin.

Because of the presence of the pin(s), if applicable the invention can make it possible to avoid a problem with burning.

The presence of a pin or of a plurality of pins also permits accurate positioning of one of the boards relative to the other, before welding takes place.

The presence of a pin or of a plurality of pins also makes it possible to facilitate the welding operation, and to improve the quality of the welding (form of a meniscus of the fused metals). The welding can for example be carried out very neatly.

If required, the pins are aligned in a straight line.

For example, the pin(s) is/are welded onto the printed circuit board which supports it/them.

If applicable, the pin of one of the boards comprises a shoulder on which the other board rests.

If required, the assembly does not have a layer of resin, and in particular thermosetting resin, deposited between the two printed circuit boards, in order to keep the boards assembled.

Advantageously, once the boards have been assembled, the pin(s) protrude(s) through the corresponding orifice(s).

As a variant, once the boards have been assembled, the orifice(s) in one of the boards receive(s) only welding material, in particular without the presence of a pin.

According to one embodiment of the invention, the assembly comprises at least one retention element, which for example is made of plastic material, and is designed to retain one of the printed circuit boards against the other at least temporarily, in particular before the welding is carried out.

If applicable, this retention element can be removed from the assembly after the welding has been carried out.

The printed circuit boards are preferably kept assembled exclusively by the welding and the pins.

If applicable, the assembly does not have a retention element, and in particular a stiffener, in order to retain one of the printed circuit boards against the other permanently after the welding has been carried out.

For example, one of the printed circuit boards, and in particular the rigid one, bears at least one electronic component, and in particular bears at least one source of light, and in particular at least one LED.

According to one embodiment of the invention, one of the printed circuit boards is in contact with a heat dissipater element, which for example comprises cooling fins.

Preferably, the assembly is designed to be fitted in a lighting and/or signalling device of a motor vehicle.

The subject of the invention is also a printed circuit board comprising at least one conductive track and a pin which is in electrical contact with this track, this pin being for example welded onto this track.

The subject of the invention is also a method for forming an electrical connection between two printed circuit boards, the method comprising the following steps:
bringing the printed circuit boards together; and
carrying out laser welding in order to connect the two printed circuit boards electrically.

If applicable, after the welding has been carried out, the welding trace(s) is/are inspected optically, for example by using visible light.

### BRIEF DESCRIPTION OF THE ACCOMPANYING DRAWINGS

The invention will be able to be better understood by reading the following detailed description of non-limiting embodiments of it, and by examining the attached drawing, in which:

FIG. 1 represents an assembly according to an embodiment of the invention, schematically, partially, and in perspective;

FIG. 2 illustrates the assembly in FIG. 1 schematically and partially, according to a cross-section in accordance with II-II;

FIG. 3 represents an assembly according to another embodiment of the invention, schematically, partially, and in perspective;

FIG. 4 illustrates the assembly in FIG. 3 schematically and partially, according to a cross-section in accordance with IV-IV;

FIG. 5 represents an assembly according to another embodiment of the invention, schematically, partially, and in perspective; and

FIG. 6 illustrates the assembly in FIG. 5 schematically and partially, according to a cross-section in accordance with VI-VI.

### DETAILED DESCRIPTION OF THE PREFERRED EMBODIMENTS

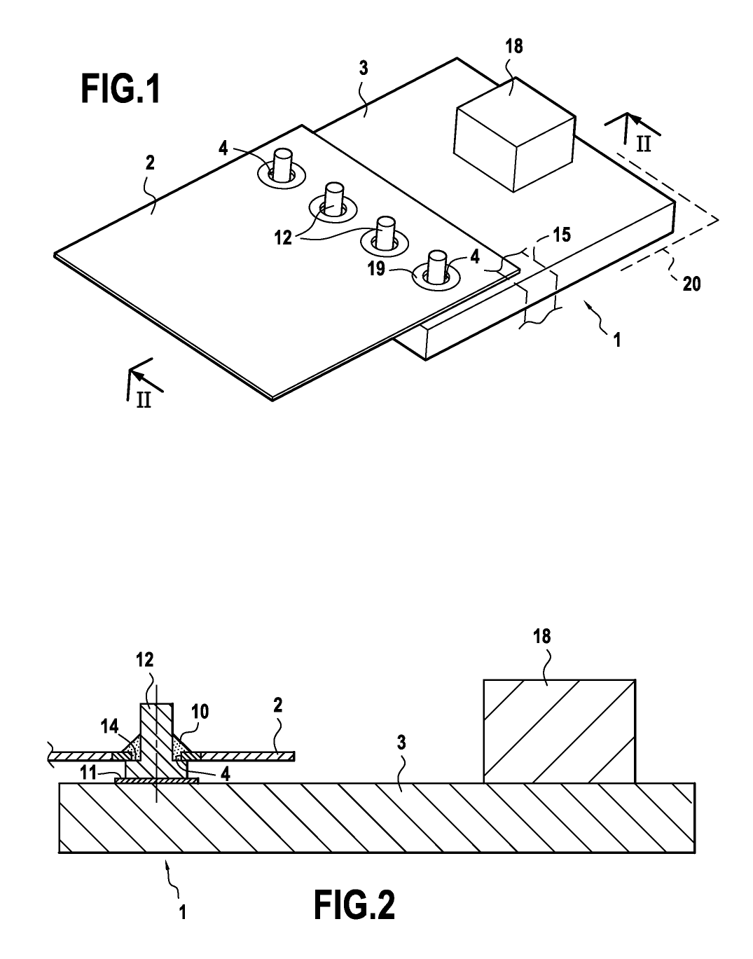

FIGS. 1 and 2 represent an assembly of two electric boards 2 and 3, i.e., two printed circuit boards, the two boards being welded to one another.

The board 2 comprises a plurality of circular orifices 4, which are aligned on a segment of a straight line, each showing a trace 10 of the welding (see FIG. 2).

In the example described, the printed circuit board 2 is flexible, and the board 3 is rigid.

The welding trace 10 corresponds to welding material deposited, for example tin. This welding trace which is added during the welding can for example have the form of a meniscus.

The deposit of welding material extends through the orifice in the board.

Each board 2 and 3 comprises a plurality of conductive tracks 11, and the deposit of welding material joins the conductive track of one of the boards to the conductive track of the other board.

The rigid board 3 comprises a plurality of pins 12, each of which is designed to be engaged in one of the orifices 4 in the other board 2, and the deposit of welding material is in contact with this pin 12.

The pins 12 are aligned along a straight line.

For example, the pins 12 are welded onto the printed circuit board 3 which supports them.

Each pin 12 comprises a shoulder 14 on which the other board 2 rests.

Once the boards have been assembled, the pins 12 protrude through the corresponding orifices 4.

These orifices 4 are each bordered by a ring 19, which for example is made of copper, which ring 19 is in contact with the welding metal added.

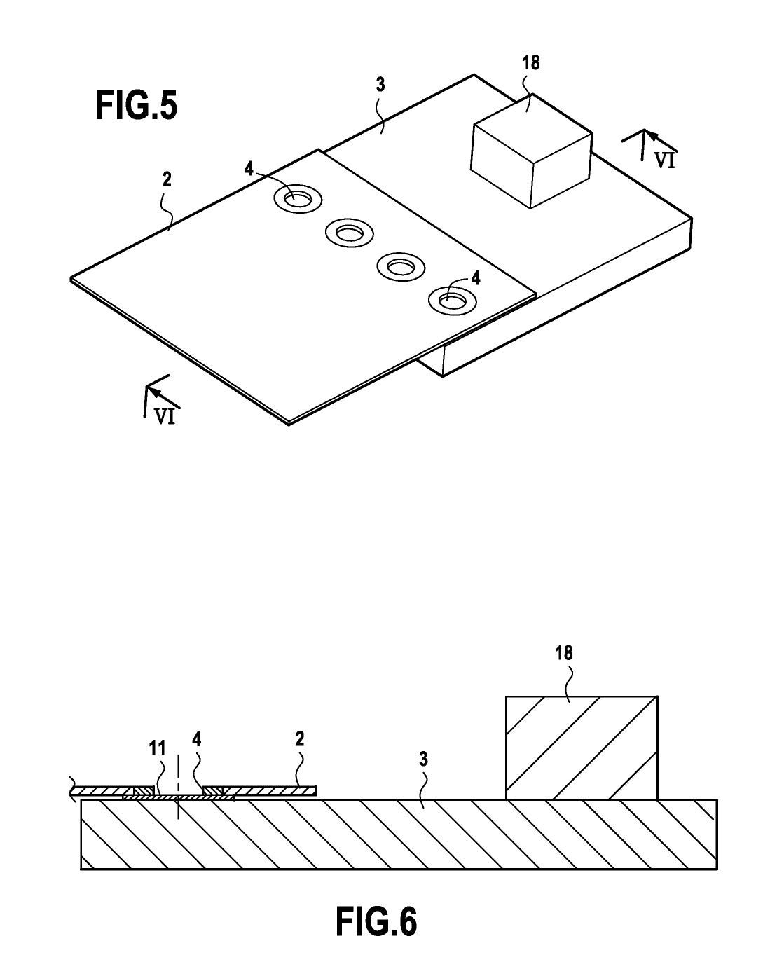

As a variant, as illustrated in FIGS. 5 and 6, once the boards 2 and 3 have been assembled, the orifices 4 in the board 2 receive only welding material, without the presence of a pin.

The board 3 does not bear any connection pin.

According to one embodiment of the invention, the assembly 1 comprises at least one retention element 15 (represented highly schematically in broken outline in FIG. 1), which for example is made of plastic material, and is designed to retain one of the printed circuit boards against the other, in particular at least before the welding is carried out.

The printed circuit board 3 supports at least one electronic component 18, which in particular supports at least one source of light, and in particular at least one LED.

In the example in FIG. 1, the printed circuit board 3 is in contact with a heat dissipater element 20, which for example comprises cooling fins.

The assembly 1 is designed to be fitted in a lighting and/or signalling device of a motor vehicle, which for example can produce a low beam and/or a high beam.

It will be appreciated that the invention is not limited to the above-described embodiments.

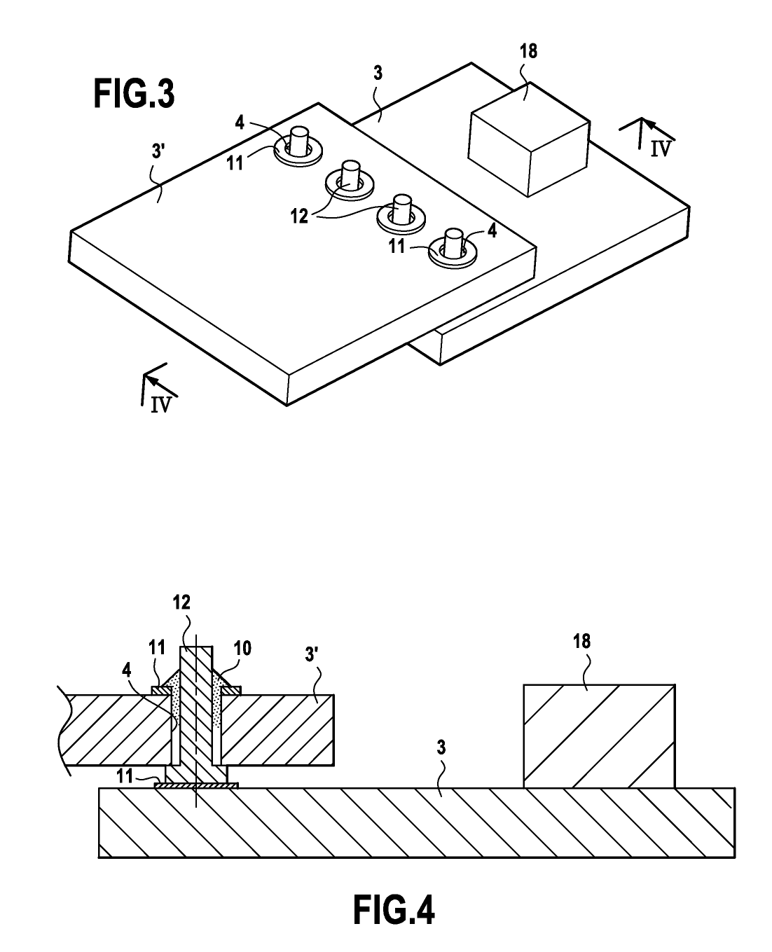

For example, as illustrated in FIGS. 3 and 4, the assembly can comprise two rigid printed circuit boards 3 and 3′.

While the method herein described, and the form of apparatus for carrying this method into effect, constitute preferred embodiments of this invention, it is to be understood that the invention is not limited to this precise method and form of apparatus, and that changes may be made in either without departing from the scope of the invention, which is defined in the appended claims.

What is claimed is:

1. An assembly of at least two electric boards, and in particular two printed circuit boards, the at least two electric boards being welded to one another, wherein at least one of the two boards comprises at least one orifice which shows a trace of the welding.

2. The assembly according to claim 1, wherein at least one of the boards is a flexible printed circuit board.

3. The assembly according to claim 1, wherein at least one of the boards is a rigid printed circuit board.

4. The assembly according to claim 1, wherein the deposit of welding material extends through the orifice in the board.

5. The assembly according to claim 1, wherein each board comprises at least one conductive track, and the deposit of welding material joins the conductive track of one of the boards to the conductive track of the other board.

6. The assembly according to claim 1, wherein at least one of the boards, which for example is rigid, comprises at least one pin, and for example a plurality of pins, which is/are designed to be engaged in the orifice in the other board, and the deposit of welding material is in contact with this pin.

7. The assembly according to claim 1, wherein the pin(s) is/are welded onto the corresponding printed circuit board.

8. The assembly according to claim 6, wherein once the boards have been assembled, the pin(s) protrude(s) through the corresponding orifice(s).

9. The assembly according to claim 1, wherein once the boards have been assembled, the orifice(s) in one of the boards receive(s) only welding material, in particular without the presence of a pin.

10. The assembly according to claim 1, wherein said assembly comprises at least one retention element, which for example is made of plastic material, and is designed to retain one of the printed circuit boards against the other.

11. The assembly according to claim 1, wherein one of the printed circuit boards, and in particular the rigid one, bears at least one electronic component, and in particular bears at least one source of light, and in particular at least one LED.

12. The assembly according to claim 1, wherein said assembly is designed to be fitted in a lighting and/or signalling device of a motor vehicle.

13. A printed circuit board comprising at least one conductive track and a pin which is in electrical contact with this track, said pin being for example welded onto this track.

14. A method for forming an electrical connection between two printed circuit boards, the method comprising the following steps:
bringing the printed circuit boards together; and
carrying out welding in order to connect the two printed circuit boards electrically.

15. The method according to claim 14, wherein after the welding has been carried out, the welding trace(s) is/are inspected optically.

16. The method according to claim 14, wherein said welding is laser welding.

17. The assembly according to one claim 7, wherein once the boards have been assembled, the pin(s) protrude(s) through the corresponding orifice(s).

18. The assembly according to claim 2, wherein once the boards have been assembled, the orifice(s) in one of the boards receive(s) only welding material, in particular without the presence of a pin.

19. The assembly according to claim 3, wherein once the boards have been assembled, the orifice(s) in one of the boards receive(s) only welding material, in particular without the presence of a pin.

20. The assembly according to claim 4, wherein once the boards have been assembled, the orifice(s) in one of the boards receive(s) only welding material, in particular without the presence of a pin.
